(19) United States
(12) Patent Application Publication
(10) Pub. No.: US 2014/0131084 A1
(43) Pub. Date: May 15, 2014

(54) CAPACITOR EMBEDDED SUBSTRATE

(71) Applicant: Samsung Electro-Mechanics Co., Ltd., Suwon (KR)

(72) Inventors: Doo Hwan Lee, Daejeon (KR); Yul Kyo Chung, Yongin (KR)

(73) Assignee: Samsung Electro-Mechanics Co., Ltd., Suwon (KR)

(21) Appl. No.: 14/051,157

(22) Filed: Oct. 10, 2013

(30) Foreign Application Priority Data
Nov. 15, 2012 (KR) 10-2012-0129425

(51) Int. Cl. H05K 1/18; H05K 1/02

(52) U.S. Cl. CPC H05K 1/185; H05K 1/0271
USPC 174/260

(57) ABSTRACT

A capacitor embedded substrate that can implement low impedance over a wide frequency band and improve heat radiation performance and signal transmission performance at the same time by embedding a plurality of capacitors having different capacitances in a laminated core and connecting the capacitors in parallel.

### CROSS-REFERENCE TO RELATED APPLICATIONS

Claim and incorporate by reference domestic priority application and foreign priority application as follows:

### “CROSS REFERENCE TO RELATED APPLICATION

This application claims the benefit under 35 U.S.C. Section 119 of Korean Patent Application Serial No. 10-2012-0129425, entitled filed Nov. 15, 2012, which is hereby incorporated by reference in its entirety into this application.”

### BACKGROUND OF THE INVENTION

1. Field of the Invention

The present invention relates to a capacitor embedded substrate.

2. Description of the Related Art

In recent times, with miniaturization and slimming of electronic devices, a processing speed of electronic components included in the electronic devices becomes faster.

Accordingly, techniques of embedding electronic components for power stabilization, such as capacitors, in a substrate to stably supply power to active elements such as arithmetic processing units have been introduced through Patent Document 1 etc.

A processing speed of the arithmetic processing unit may be determined by several conditions, and one of the conditions is stable power supply.

That is, in order to operate the active element at higher speed, thermal conductivity and electrical conductivity should be improved and impedance of wiring should be reduced.

Therefore, in case of a substrate on which high performance active elements are mounted, in order to improve a signal transmission speed, it is required to improve conductivity between conductive patterns and the embedded elements.

Further, as the size of the active element is reduced with the improvement of performance of the active element, improvement of heat radiation performance and miniaturization of the conductive pattern are also required.

Further, it is required to maintain low impedance while processing RF signals of various frequency bands.

### RELATED ART DOCUMENT

### Patent Document

Patent Document 1: Korean Patent Laid-open Publication No. 2010-0030151

### SUMMARY OF THE INVENTION

The present invention has been invented in order to overcome the above-described problems and it is, therefore, an object of the present invention to provide a capacitor embedded substrate that can maintain low impedance over a wide frequency band.

Further, it is another object of the present invention to provide a capacitor embedded substrate that can implement high heat radiation performance and high electrical conductivity while maintaining low impedance over a wide frequency band.

In accordance with one aspect of the present invention to achieve the object, there is provided a capacitor embedded substrate having a plurality of capacitors with different capacitances embedded therein, wherein the capacitors may be electrically connected in parallel.

At this time, the capacitors may be embedded in an insulating portion having a core in one region.

In accordance with another aspect of the present invention to achieve the object, there is provided a capacitor embedded substrate including: an insulating portion; a first capacitor and a second capacitor provided inside the insulating portion; a first conductor pattern provided on an outer surface of the insulating portion; and a via having one side in contact with external electrodes of the first capacitor and the second capacitor and the other side in contact with the first conductor pattern, wherein the first capacitor and the second capacitor may have different capacitances, and the first conductor pattern may be provided to connect the first capacitor and the second capacitor in parallel.

At this time, the capacitance of the first capacitor may be several to hundreds of pF or several to hundreds of nF, and the second capacitor may have a capacitance larger than that of the first capacitor.

Further, the capacitance of the first capacitor may be several to hundreds of pF, and the capacitance of the second capacitor may be several to hundreds of nF.

Further, the capacitance of the first capacitor may be several to hundreds of nF, and the capacitance of the second capacitor may be several to hundreds of uF.

In accordance with another aspect of the present invention to achieve the object, there is provided a capacitor embedded substrate including: a core; a first capacitor and a second capacitor provided inside the core; a first build-up layer including a second conductor pattern formed on an outer surface of the core and a first build-up via having one surface in contact with the second conductor pattern; a first conductor pattern formed on an outer surface of the first build-up layer to be in contact with the other surface of the first build-up via; and a core via having one side in contact with external electrodes of the first capacitor and the second capacitor and the other side in contact with the second conductor pattern, wherein the first capacitor and the second capacitor may have different capacitances, and the first capacitor and the second capacitor may be connected in parallel by the first conductor pattern or the second conductor pattern.

In accordance with another aspect of the present invention to achieve the object, there is provided a capacitor embedded substrate including: a laminated core formed by laminating at least two layers of cores each having a core via; a first capacitor and a second capacitor provided inside the laminated core; a second build-up layer including a second conductor pattern formed on an outer surface of the laminated core and a second build-up via having one surface in contact with the second conductor pattern; a first build-up layer including a third conductor pattern formed on an outer surface of the second build-up layer to be in contact with the other surface of the second build-up via and a first build-up via having one surface in contact with the third conductor pattern; and a first conductor pattern formed on an outer surface of the first build-up layer to be in contact with the other surface of the first build-up via, wherein some of the core vias may have one side in contact with external electrodes of the first capacitor and the second capacitor and the other side in contact with the second conductor pattern, the first capacitor and the second capacitor may have different capacitances, and the first capacitor and the second capacitor may be connected in parallel by the first conductor pattern or the second conductor pattern.

At this time, at least one of the first capacitor and the second capacitor may be provided in a cavity formed inside the laminated core.

Further, among the second conductor patterns, at least one of the second conductor patterns which are in contact with the other side of the core vias having one side in contact with the external electrodes of the first capacitor and the second capacitor may be in contact with a plurality of second build-up vias.

Further, the second build-up layer may further include a glass fiber.

Further, the second build-up layer may further include a material having a value of coefficient of thermal expansion between a value of coefficient of thermal expansion of the laminated core and a value of coefficient of thermal expansion of the first build-up layer.

In accordance with another aspect of the present invention to achieve the object, there is provided a capacitor embedded substrate including: an insulating portion; a first capacitor, a second capacitor, and a third capacitor provided inside the insulating portion; a first conductor pattern provided on an outer surface of the insulating portion; and a via having one side in contact with external electrodes of the first capacitor, the second capacitor, and the third capacitor and the other side in contact with the first conductor pattern, wherein the first capacitor, the second capacitor, and the third capacitor may have different capacitances, and the first conductor pattern may be provided to connect the first capacitor, the second capacitor, and the third capacitor in parallel.

At this time, the capacitance of the first capacitor may be several to hundreds of pF or several to hundreds of nF, the second capacitor may have a capacitance larger than that of the first capacitor, and the third capacitor may have a capacitance larger than that of the second capacitor.

Further, the capacitance of the first capacitor may be several to hundreds of pF or several to tens of nF, the capacitance of the second capacitor may be several to hundreds of uF, and the third capacitor may have a capacitance larger than that of the second capacitor.

Further, the capacitance of the first capacitor may be several to hundreds of pF, the capacitance of the second capacitor may be several to hundreds of nF, and the capacitance of the third capacitor may be several to tens of uF.

In accordance with another aspect of the present invention to achieve the object, there is provided a capacitor embedded substrate including: a core; a first capacitor, a second capacitor, and a third capacitor provided inside the core; a first build-up layer including a second conductor pattern formed on an outer surface of the core and a first build-up via having one surface in contact with the second conductor pattern; a first conductor pattern formed on an outer surface of the first build-up layer to be in contact with the other surface of the first build-up via; and a core via having one side in contact with external electrodes of the first capacitor, the second capacitor, and the third capacitor and the other side in contact with the second conductor pattern, wherein the first capacitor, the second capacitor, and the third capacitor may have different capacitances and the first capacitor, the second capacitor, and the third capacitor may be connected in parallel by the first conductor pattern or the second conductor pattern.

Of course, in some cases, only a combination of two capacitors may improve stability of power supply, and more than four capacitors may be combined.

Here, the core may be formed by laminating a plurality of layers.

In accordance with another aspect of the present invention to achieve the object, there is provided a capacitor embedded substrate including: a laminated core formed by laminating at least two layers of cores each having a core via; a first capacitor, a second capacitor, and a third capacitor provided inside the laminated core; a second build-up layer including a second conductor pattern formed on an outer surface of the laminated core and a second build-up via having one surface in contact with the second conductor pattern; a first build-up layer including a third conductor pattern formed on an outer surface of the second build-up layer to be in contact with the other surface of the second build-up via and a first build-up via having one surface in contact with the third conductor pattern; and a first conductor pattern formed on an outer surface of the first build-up layer to be in contact with the other surface of the first build-up via, wherein some of the core vias may have one side in contact with external electrodes of the first capacitor, the second capacitor, and the third capacitor and the other side in contact with the second conductor pattern, the first capacitor, the second capacitor, and the third capacitor may have different capacitances, and the first capacitor, the second capacitor, and the third capacitor may be connected in parallel by the first conductor pattern or the second conductor pattern.

Here, it is to be understood that different combinations, that is, various combinations such as a combination of the first capacitor and the second capacitor or a combination of the second capacitor and the third capacitor are possible according to the need of a designer.

At this time, at least one of the first capacitor, the second capacitor, and the third capacitor may be provided in a cavity formed inside the laminated core.

Further, among the second conductor patterns, at least one of the second conductor patterns which are in contact with the other side of the cores via having one side in contact with the external electrodes of the first capacitor, the second capacitor, and the third capacitor may be in contact with a plurality of second build-up vias.

Further, the second build-up layer may further include a glass fiber.

Further, the second build-up layer may further include a material having a value of coefficient of thermal expansion between a value of coefficient of thermal expansion of the laminated core and a value of coefficient of thermal expansion of the first build-up layer.

Further, the number of layers of the cores positioned in a region vertically above the first capacitor and in a region vertically under the first capacitor may be greater than the number of layers of the cores positioned in a region vertically above the second capacitor and in a region vertically under the second capacitor, and the number of layers of the cores positioned in the region vertically above the second capacitor and in the region vertically under the second capacitor may be greater than the number of layers of the cores positioned in a region vertically above the third capacitor and in a region vertically under the third capacitor.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing a capacitor embedded substrate in accordance with a first embodiment of the present invention;

FIG. 2 is a view schematically showing a capacitor embedded substrate in accordance with a second embodiment of the present invention;

FIG. 3 is a view schematically showing a capacitor embedded substrate in accordance with a third embodiment of the present invention; and

FIG. 4 is a view for explaining an impedance reduction effect in accordance with an embodiment of the present invention.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configurations and operational effects of the present invention will be described in detail with reference to the accompanying drawings.

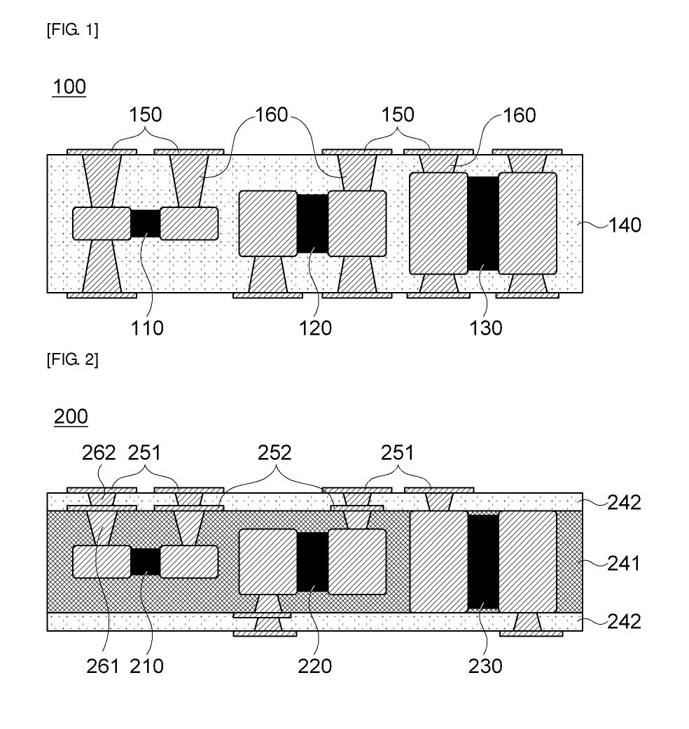

FIG. 1 is a view schematically showing a capacitor embedded substrate 100 in accordance with a first embodiment of the present invention.

The capacitor embedded substrate 100 in accordance with the first embodiment of the present invention is a substrate in which a plurality of capacitors 110, 120, and 130 having different capacitances are embedded.

At this time, the plurality of capacitors 110, 120, and 130 may be embedded in an insulating portion 140, and although not shown, a core may be provided in one region inside the insulating portion 140.

Referring to FIG. 1, the capacitor embedded substrate in accordance with the first embodiment of the present invention may include the insulating portion 140, the first to third capacitors 110, 120, and 130, a first conductor pattern 150, and a via 160.

At this time, the first to third capacitors 110, 120, and 130 may have different capacitances.

Further, the first to third capacitors 110, 120, and 130 may be connected electrically in parallel by the vias 160 and the first conductor patterns 150.

For example, the capacitance of the first capacitor 110 may be several to hundreds of pF, the capacitance of the second capacitor 120 may be several to hundreds of nF, and the capacitance of the third capacitor 130 may be several to hundreds of uF.

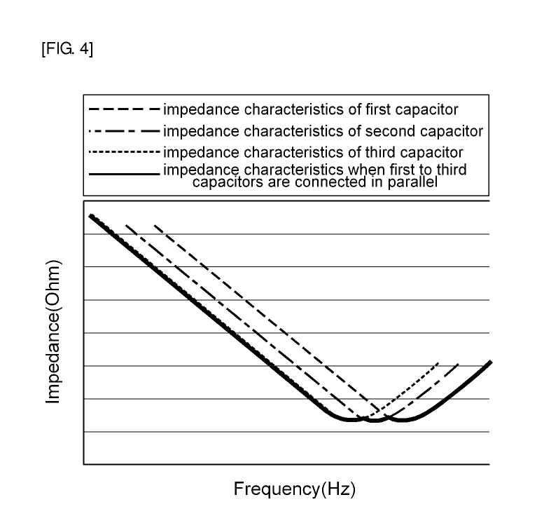

FIG. 4 is a view for explaining an impedance reduction effect in accordance with an embodiment of the present invention. Referring to FIG. 4, it is to be understood that the smaller the capacitance of the capacitor, the lower the impedance in a high frequency band.

For example, when the first capacitor 110 having a capacitance of picofarads, and the second capacitor 120 having a capacitance of nanofarads, and the third capacitor 130 having a capacitance of microfarads are connected in parallel, it is possible to exhibit impedance characteristics as shown by the solid line in FIG. 4. Accordingly, it is possible to implement low impedance characteristics over a wider frequency band than the prior art.

Meanwhile, the first to third capacitors 110, 120, and 130 may be embedded in the substrate by being provided inside the insulating portion 140.

At this time, the first conductor patterns 150 may be provided on an outer surface of the insulating portion 140, and the vias 160 may be provided between external electrodes of the first to third capacitors 110, 120, and 130 and the first conductor patterns 150 to connect the first to third capacitors 110, 120, and 130 electrically in parallel.

FIG. 2 is a view schematically showing a capacitor embedded substrate 200 in accordance with a second embodiment of the present invention.

A repeated description similar to the description of the above-described first embodiment will be omitted.

Referring to FIG. 2, the capacitor embedded substrate 200 in accordance with the second embodiment of the present invention may consist of a core 241 and a first build-up layer 242 and may be implemented by embedding first to third capacitors 210, 220, and 230 inside the core 241.

At this time, the core 241 may perform a role of improving heat radiation performance of the capacitor embedded substrate 200.

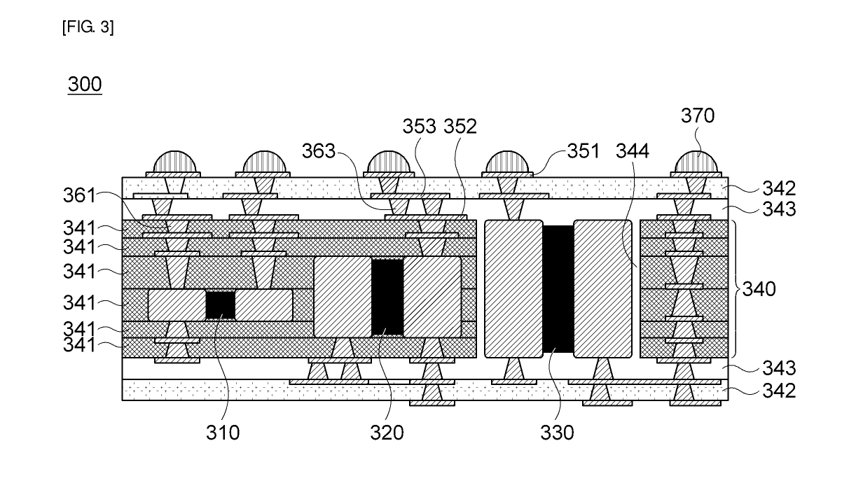

FIG. 3 is a view schematically showing a capacitor embedded substrate 300 in accordance with a third embodiment of the present invention.

A repeated description similar to those of the above-described first and second embodiments will be omitted.

Referring to FIG. 3, the capacitor embedded substrate 300 in accordance with the third embodiment of the present invention may include a laminated core 340, first to third capacitors 310, 320, and 330, a first build-up layer 342, a second build-up layer 343, and a first conductor pattern 351.

First, the laminated core is formed by laminating a plurality of cores 341 having a core via 361 on each layer.

In order to minimize warpage due to thermal stress, typically, a core is formed using a material with a coefficient of thermal expansion (CTE) of less than 10 ppm/degree C. However, when processing a material with a low coefficient of thermal expansion using a mechanical drill, a drill blade made of a high strength material is required and processing efficiency is deteriorated.

Considering this problem, laser may be used when processing a core via hole. However, when the core is thick, since the core via hole is processed by irradiating laser to both surfaces of the core, it is common that the core via hole is formed in the shape of a sandglass.

However, in the core via hole processed by laser in the shape of a sandglass, a cross-sectional area of a center portion in the thickness direction of the core is smaller than a cross-sectional area of upper and lower portions of the core via hole. At this time, the cross-sectional area of the upper and lower portions of the core via hold should be proportionally increased to increase the cross-sectional area of the center portion.

Accordingly, in a process of filling the entire inside of the core via hole having a sandglass shape with conductive metal such as copper, there are difficulties in completely filling the inside of the core via hole having a large cross-sectional area.

Further, in this structure, there are additional difficulties in implementing a stack structure (high speed signal transmission structure) between the core vias, thus exerting a bad influence on wiring density.

Therefore, in the core via hole having a sandglass shape, several problems are caused by the increase in the cross-sectional area of the center portion of the thickness direction.

In order to overcome this problem, the capacitor embedded substrate 300 in accordance with the third embodiment of the present invention can minimize the cross-sectional area of the via which electrically connects between one surface and the other surface of the laminated core 340 while thickening the laminated core 340 by laminating the cores 341 having a predetermined thickness in a plurality of layers in a state in which the core vias 361 are formed in the cores 341.

At this time, the cores 341, which form the laminated core 340, may have the same thickness or different thicknesses according to the need.

Accordingly, it is possible to improve a signal processing speed by implementing improvement in electrical conductivity as well as improvement in heat radiation performance.

Meanwhile, the first to third capacitors 310, 320, and 330 may be embedded in the laminated core 340. At this time, a cavity 344 may be provided to embed at least one of the first to third capacitors 310, 320, and 330 in the laminated core 340.

Further, the capacitance of the capacitors may be adjusted according to the size of the capacitors. As shown, when the size of the first to third capacitors 310, 320, and 330 satisfies the relation: [the first capacitor 310<the second capacitor 320<the third capacitor 330], the capacitance thereof also may satisfy the relation: [capacitance of the first capacitor 310<capacitance of the second capacitor 320<capacitance of the third capacitor 330].

Further, in setting the size and capacitance of the capacitors like this, the thickness of the capacitors may be determined differentially.

Therefore, the number of layers of the cores 341 positioned in regions vertically above and under the first capacitor 310 may be greater than the number of layers of the cores 341 positioned in regions vertically above and under the second capacitor 320, and the number of layers of the cores 341 positioned in the regions vertically above and under the second capacitor 320 may be greater than the number of layers of the cores 341 positioned in regions vertically above and under the third capacitor 330.

Accordingly, it is possible to improve efficiency of the process of embedding the capacitors in the laminated core 340, and it is possible to reduce the size and thickness of the capacitor embedded substrate 300 by minimizing the space required for embedding the capacitors in the laminated core 340.

Meanwhile, the second build-up layer 343 may be provided on a surface of the laminated core 340, and the first build-up layer 342 may be provided on a surface of the second build-up layer 343.

At this time, the second build-up layer 343 may include a second conductor pattern 352 and a second build-up via 363. The first build-up layer 342 may include a first build-up via 362 and the first conductor pattern 351 may be provided on a surface of the first build-up layer 342.

Here, the second build-up layer 343 may include a glass fiber or a material having a value of coefficient of thermal expansion between a value of coefficient of thermal expansion of the laminated core 340 and a value of coefficient of thermal expansion of the first build-up layer 342.

As the capacitor embedded substrate 300 is made of materials having different physical properties, such as the laminated core 340 and the build-up layers 342 and 343, non-uniform expansion and contraction may occur due to thermal impact in the process of manufacturing and using the capacitor embedded substrate 300, and cracks may occur on a boundary surface between the laminated core 340 and the build-up layers 342 and 343 due to this phenomenon.

This problem may emerge as a serious problem when the capacitor embedded substrate 300 becomes slimmer and the configuration of the capacitor embedded substrate 300 becomes complicated.

In order to overcome this problem, in the capacitor embedded substrate 300 in accordance with the third embodiment of the present invention, the second build-up layer 343 includes a glass fiber or a material that can reduce a difference in the coefficient of thermal expansion between the laminated core 340 and the first build-up layer 342.

Meanwhile, the second conductor pattern 352 is in direct contact with the core via 361, and the second build-up via 363 is in direct contact with the second conductor pattern 352 and the third conductor pattern 353 to implement electrical connection.

At this time, the more the signal transmission path between the first to third capacitors 310, 320, and 330 and the first conductor pattern 351 is secured, the higher the utilization of the capacitance of the first to third capacitors 310, 320, and 330 is.

For this, in the capacitor embedded substrate 300 in accordance with the third embodiment of the present invention, a plurality of second build-up vias 363 are in contact with the second conductor pattern 352 in direct contact with the core via 361 of which one side is in contact with the external electrodes of the first to third capacitors 310, 320, and 330.

At this time, as shown in FIG. 3, the core vias 361, whose one sides are in contact with the external electrodes of the first to third capacitors 310, 320, and 330, may be connected in more than 2 layers.

Accordingly, the signal transmission path between the first to third capacitors 310, 320, and 330 and the first conductor pattern can be widened than the prior art. As a result, it is possible to efficiently utilize the capacitance of the first to third capacitors 310, 320, and 330.

The present invention configured as above can implement low impedance characteristics over a wider frequency band than the prior art and improve a signal processing speed by implementing improvement in electrical conductivity as well as improvement in heat radiation performance.

Further, it is possible to miniaturize and slim the capacitor embedded substrate and efficiently utilize the capacitance of the embedded capacitor.

What is claimed is:

1. A capacitor embedded substrate having a plurality of capacitors with different capacitances embedded therein, wherein the capacitors are electrically connected in parallel.

2. The capacitor embedded substrate according to claim 1, wherein the capacitors are embedded in an insulating portion having a core in one region.

3. A capacitor embedded substrate comprising:
an insulating portion;
a first capacitor and a second capacitor provided inside the insulating portion;
a first conductor pattern provided on an outer surface of the insulating portion; and
a via having one side in contact with external electrodes of the first capacitor and the second capacitor and the other side in contact with the first conductor pattern, wherein the first capacitor and the second capacitor have different capacitances, and
the first conductor pattern is provided to connect the first capacitor and the second capacitor in parallel.

4. The capacitor embedded substrate according to claim 3, wherein the capacitance of the first capacitor is several to hundreds of pF, and
the second capacitor has a capacitance larger than that of the first capacitor.

5. The capacitor embedded substrate according to claim 3, wherein the capacitance of the first capacitor is several to hundreds of pF, and
the capacitance of the second capacitor is several to hundreds of nF.

6. The capacitor embedded substrate according to claim 3, wherein the capacitance of the first capacitor is several to hundreds of nF, and
the second capacitor has a capacitance larger than that of the first capacitor.

7. The capacitor embedded substrate according to claim 3, wherein the capacitance of the first capacitor is several to hundreds of nF, and
the capacitance of the second capacitor is several to hundreds of uF.

8. The capacitor embedded substrate according to claim 3, wherein a core is provided in one region inside the insulating portion.

9. A capacitor embedded substrate comprising:
a core;
a first capacitor and a second capacitor provided inside the core;
a first build-up layer comprising a second conductor pattern formed on an outer surface of the core and a first build-up via having one surface in contact with the second conductor pattern;
a first conductor pattern formed on an outer surface of the first build-up layer to be in contact with the other surface of the first build-up via; and
a core via having one side in contact with external electrodes of the first capacitor and the second capacitor and the other side in contact with the second conductor pattern, wherein the first capacitor and the second capacitor have different capacitances, and
the first capacitor and the second capacitor are connected in parallel by the first conductor pattern or the second conductor pattern.

10. The capacitor embedded substrate according to claim 9, wherein the capacitance of the first capacitor is several to hundreds of pF, and
the second capacitor has a capacitance larger than that of the first capacitor.

11. The capacitor embedded substrate according to claim 9, wherein the capacitance of the first capacitor is several to hundreds of pF, and
the capacitance of the second capacitor is several to hundreds of nF.

12. The capacitor embedded substrate according to claim 9, wherein the capacitance of the first capacitor is several to hundreds of nF, and
the second capacitor has a capacitance larger than that of the first capacitor.

13. The capacitor embedded substrate according to claim 9, wherein the capacitance of the first capacitor is several to hundreds of nF, and
the capacitance of the second capacitor is several to hundreds of uF.

14. The capacitor embedded substrate according to claim 9, wherein the core is formed by laminating a plurality of layers.

15. A capacitor embedded substrate comprising:
a laminated core formed by laminating at least two layers of cores each having a core via;
a first capacitor and a second capacitor provided inside the laminated core;
a second build-up layer comprising a second conductor pattern formed on an outer surface of the laminated core and a second build-up via having one surface in contact with the second conductor pattern;
a first build-up layer comprising a third conductor pattern formed on an outer surface of the second build-up layer to be in contact with the other surface of the second build-up via and a first build-up via having one surface in contact with the third conductor pattern; and
a first conductor pattern formed on an outer surface of the first build-up layer to be in contact with the other surface of the first build-up via, wherein some of the core vias have one side in contact with external electrodes of the first capacitor and the second capacitor and the other side in contact with the second conductor pattern,
the first capacitor and the second capacitor have different capacitances, and
the first capacitor and the second capacitor are connected in parallel by the first conductor pattern or the second conductor pattern.

16. The capacitor embedded substrate according to claim 15, wherein at least one of the first capacitor and the second capacitor is provided in a cavity formed inside the laminated core.

17. The capacitor embedded substrate according to claim 15, wherein among the second conductor patterns, at least one of the second conductor patterns which are in contact with the other side of the core vias having one side in contact with the external electrodes of the first capacitor and the second capacitor is in contact with a plurality of second build-up vias.

18. The capacitor embedded substrate according to claim 15, wherein the second build-up layer further comprises a glass fiber.

19. The capacitor embedded substrate according to claim 15, wherein the second build-up layer further comprises a material having a value of coefficient of thermal expansion between a value of coefficient of thermal expansion of the laminated core and a value of coefficient of thermal expansion of the first build-up layer.

20. The capacitor embedded substrate according to claim 15, wherein the capacitance of the first capacitor is several to hundreds of pF, and
the second capacitor has a capacitance larger than that of the first capacitor.

21. The capacitor embedded substrate according to claim 15, wherein the capacitance of the first capacitor is several to hundreds of pF, and
the capacitance of the second capacitor is several to hundreds of nF.

22. The capacitor embedded substrate according to claim 15, wherein the capacitance of the first capacitor is several to hundreds of nF, and
the second capacitor has a capacitance larger than that of the first capacitor.

23. The capacitor embedded substrate according to claim 15, wherein the capacitance of the first capacitor is several to hundreds of nF, and
the capacitance of the second capacitor is several to hundreds of uF.

24. The capacitor embedded substrate according to claim 15, wherein the number of layers of the cores positioned in a region vertically above the first capacitor and in a region vertically under the first capacitor is greater than the number of layers of the cores positioned in a region vertically above the second capacitor and in a region vertically under the second capacitor.

25. A capacitor embedded substrate comprising:
an insulating portion;
a first capacitor, a second capacitor, and a third capacitor provided inside the insulating portion;
a first conductor pattern provided on an outer surface of the insulating portion; and
a via having one side in contact with external electrodes of the first capacitor, the second capacitor, and the third capacitor and the other side in contact with the first conductor pattern, wherein the first capacitor, the second capacitor, and the third capacitor have different capacitances, and
the first conductor pattern is provided to connect the first capacitor, the second capacitor, and the third capacitor in parallel.

26. The capacitor embedded substrate according to claim 25, wherein the capacitance of the first capacitor is several to hundreds of pF,
the second capacitor has a capacitance larger than that of the first capacitor, and
the third capacitor has a capacitance larger than that of the second capacitor.

27. The capacitor embedded substrate according to claim 26, wherein the capacitance of the second capacitor is several to hundreds of nF.

28. The capacitor embedded substrate according to claim 27, wherein the capacitance of the third capacitor is several to hundreds of uF.

29. The capacitor embedded substrate according to claim 25, wherein the capacitance of the first capacitor is several to hundreds of nF,
the second capacitor has a capacitance larger than that of the first capacitor, and
the third capacitor has a capacitance larger than that of the second capacitor.

30. The capacitor embedded substrate according to claim 29, wherein the capacitance of the second capacitor is several to hundreds of uF.

31. The capacitor embedded substrate according to claim 25, wherein a core is provided in one region inside the insulating portion.

32. A capacitor embedded substrate comprising:
a core;
a first capacitor, a second capacitor, and a third capacitor provided inside the core;
a first build-up layer comprising a second conductor pattern formed on an outer surface of the core and a first build-up via having one surface in contact with the second conductor pattern;
a first conductor pattern formed on an outer surface of the first build-up layer to be in contact with the other surface of the first build-up via; and
a core via having one side in contact with external electrodes of the first capacitor, the second capacitor, and the third capacitor and the other side in contact with the second conductor pattern, wherein the first capacitor, the second capacitor, and the third capacitor have different capacitances, and
the first capacitor, the second capacitor, and the third capacitor are connected in parallel by the first conductor pattern or the second conductor pattern.

33. The capacitor embedded substrate according to claim 32, wherein the core is formed by laminating a plurality of layers.

34. A capacitor embedded substrate comprising:
a laminated core formed by laminating at least two layers of cores each having a core via;
a first capacitor, a second capacitor, and a third capacitor provided inside the laminated core;
a second build-up layer comprising a second conductor pattern formed on an outer surface of the laminated core and a second build-up via having one surface in contact with the second conductor pattern;
a first build-up layer comprising a third conductor pattern formed on an outer surface of the second build-up layer to be in contact with the other surface of the second build-up via and a first build-up via having one surface in contact with the third conductor pattern; and
a first conductor pattern formed on an outer surface of the first build-up layer to be in contact with the other surface of the first build-up via, wherein some of the core vias have one side in contact with external electrodes of the first capacitor, the second capacitor, and the third capacitor and the other side in contact with the second conductor pattern,
the first capacitor, the second capacitor, and the third capacitor have different capacitances, and
the first capacitor, the second capacitor, and the third capacitor are connected in parallel by the first conductor pattern or the second conductor pattern.

35. The capacitor embedded substrate according to claim 34, wherein at least one of the first capacitor, the second capacitor, and the third capacitor is provided in a cavity formed inside the laminated core.

36. The capacitor embedded substrate according to claim 34, wherein among the second conductor patterns, at least one of the second conductor patterns which are in contact with the other side of the core vias having one side in contact with the external electrodes of the first capacitor, the second capacitor, and the third capacitor is in contact with a plurality of second build-up vias.

37. The capacitor embedded substrate according to claim 34, wherein the second build-up layer further comprises a glass fiber.

38. The capacitor embedded substrate according to claim 34, wherein the second build-up layer further comprises a material having a value of coefficient of thermal expansion between a value of coefficient of thermal expansion of the laminated core and a value of coefficient of thermal expansion of the first build-up layer.

39. The capacitor embedded substrate according to claim 34, wherein the capacitance of the first capacitor is several to hundreds of pF,
the capacitance of the second capacitor is several to hundreds of nF, and
the capacitance of the third capacitor is several to hundreds of uF.

40. The capacitor embedded substrate according to claim 34, wherein the number of layers of the cores positioned in a region vertically above the first capacitor and in a region vertically under the first capacitor is greater than the number of layers of the cores positioned in a region vertically above the second capacitor and in a region vertically under the second capacitor, and
the number of layers of the cores positioned in the region vertically above the second capacitor and in the region vertically under the second capacitor is greater than the number of layers of the cores positioned in a region vertically above the third capacitor and in a region vertically under the third capacitor.
